(19) United States
(12) Patent Application Publication
(10) Pub. No.: US 2026/0371584 A1
(43) Pub. Date: Nov. 19, 2026

(54) FLASH MEMORY AND FABRICATING METHOD OF THE SAME

(71) Applicant: UNITED MICROELECTRONICS CORP., Hsin-Chu City (TW)

(72) Inventors: Yen-Tsai Yi, Tainan City (TW); Wei-Shiang Huang, Tainan City (TW); Wei-Chuan Tsai, Changhua County (TW); Chih-Jung Chen, Hsinchu County (TW); Min-Han Hsieh, Kaohsiung City (TW); Jin-Yan Chiou, Tainan City (TW); Hsiang-Wen Ke, Kaohsiung City (TW)

(73) Assignee: UNITED MICROELECTRONICS CORP., Hsin-Chu City (TW)

(21) Appl. No.: 19/235,620

(22) Filed: Jun. 12, 2025

(30) Foreign Application Priority Data
May 19, 2025 (TW) 114118623

(51) Int. Cl. H10B 41/30; H10D 30/01; H10D 30/68; H10D 64/66; H10D 64/68

(52) U.S. Cl. CPC H10B 41/30; H10D 30/0411; H10D 30/6892; H10D 30/6894; H10D 64/667; H10D 64/685; H10D 64/693

(57) ABSTRACT

A flash includes a substrate. A first floating gate is disposed on the substrate. A first control gate is disposed on the first floating gate. An erase gate is disposed on one side of the first control gate, wherein the erase gate includes a metal layer, a titanium nitride layer and a silicon oxynitride layer. The silicon oxynitride layer surrounds the titanium nitride layer, and the titanium nitride layer surrounds the metal layer.

### BACKGROUND OF THE INVENTION

### 1. Field of the Invention

The present invention relates to a flash memory, and more particularly to a flash memory with enhanced erase speed and a fabricating method thereof.

### 2. Description of the Prior Art

Flash memory is one of the key components in modern semiconductor storage technologies. It features non-volatility, high integration density, and reprogrammability, and is widely applied in smartphones, solid-state drives (SSDs), wearable devices, industrial control systems, and automotive electronics. With the rapid advancement of artificial intelligence (AI), big data, and the Internet of Things (IoT), there is an increasing demand for memory devices in terms of capacity, power consumption, and response speed.

Flash memory has the ability to retain data without power, making it an indispensable storage solution in embedded systems and mobile devices. Among its various performance parameters, erase speed is one of the critical factors that affect operational efficiency and overall system performance. Conventional erase methods typically require higher voltages and longer durations, which limit data update efficiency.

To address this challenge, ongoing efforts have been made in the industry to develop new materials and structures to enhance erase speed. As the demand for faster data processing and storage continues to grow, it becomes increasingly important to improve the performance of flash memory without incurring additional manufacturing costs.

### SUMMARY OF THE INVENTION

In one embodiment of the present invention, a flash memory is provided. The flash memory includes a substrate, a first floating gate disposed on the substrate, and a first control gate disposed on the first floating gate. An erase gate is disposed on one side of the first control gate. The erase gate includes a metal layer, a titanium nitride layer, and a silicon oxynitride layer. The silicon oxynitride layer surrounds the titanium nitride layer, and the titanium nitride layer surrounds the metal layer. Such a structure enhances the erase performance of the flash memory by optimizing the nitrogen contact in the titanium nitride layer.

In another embodiment of the present invention, a fabricating method of a flash memory is provided. The method includes providing a substrate, and forming a first floating gate, a first control gate, a second floating gate, and a second control gate on the substrate. The first control gate is disposed on the first floating gate, and the second control gate is disposed on the second floating gate. A first trench is formed between the first and second control gates and between the first and second floating gates. Later, a second silicon oxide layer is formed to fill the first trench, wherein the second silicon oxide layer defines a second trench. After that, a bottom of the second trench is etched to form a third trench that extends into the substrate. Subsequently, a titanium nitride layer is formed to cover the second and third trenches. After forming the titanium nitride layer, a nitridation process is performed, in which nitrogen atoms are implanted into the titanium nitride layer using a nitrogen-containing gas as a reactive gas. Following the nitridation process, a metal layer is formed to fill the second trench and the third trench. This process enables the formation of an erase gate with a high nitrogen concentration, thereby improving erase speed and device performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a fabricating method of a flash memory according to a preferred embodiment of the present invention, wherein:

FIG. 2 depicts a stage following FIG. 1;

FIG. 3 depicts a stage following FIG. 2;

FIG. 4 depicts a stage following FIG. 3;

FIG. 5 depicts a stage following FIG. 4;

FIG. 6 depicts a stage following FIG. 5;

FIG. 7 depicts a stage following FIG. 6;

FIG. 8 depicts a stage following FIG. 7; and

FIG. 9 depicts a stage following FIG. 8.

### DETAILED DESCRIPTION

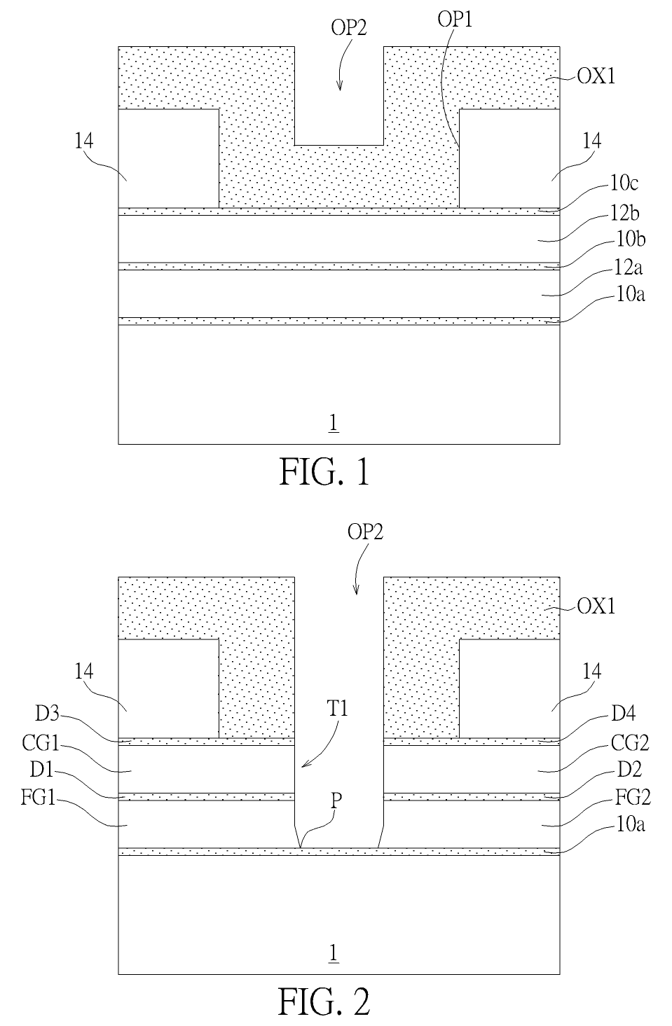

FIGS. 1 to 9 illustrate a fabricating method of a flash memory according to a preferred embodiment of the present invention.

As shown in FIG. 1, a semiconductor substrate 1 is provided. The semiconductor substrate 1 includes a silicon substrate, a germanium substrate, a gallium arsenide substrate, a silicon-germanium substrate, an indium phosphide substrate, a gallium nitride substrate, a silicon carbide substrate, or a silicon-on-insulator substrate. Then, a dielectric layer 10a, a conductive material layer 12a, a dielectric layer 10b, a conductive material layer 12b, a dielectric layer 10c, and a silicon nitride mask layer 14 are sequentially formed to cover the semiconductor substrate 1. Next, the silicon nitride mask layer 14 is patterned to form an opening OP1. Subsequently, a first silicon oxide layer OX1 is formed to conformally cover the silicon nitride mask layer 14 and the opening OP1. At this point, the first silicon oxide layer OX1 defines an opening OP2.

As shown in FIG. 2, using the first silicon oxide layer OX1 as a mask, the dielectric layer 10c, the conductive material layer 12b, the dielectric layer 10b, and the conductive material layer 12a are etched to form a first trench T1 in the dielectric layer 10c, the conductive material layer 12b, the dielectric layer 10b, and the conductive material layer 12a, wherein a bottom of the first trench T1 is defined by the dielectric layer 10a. At this point, the dielectric layer 10c, the conductive material layer 12b, the dielectric layer 10b, and the conductive material layer 12a are all segmented. The conductive material layer 12a is divided into a first floating gate FG1 and a second floating gate FG2, the conductive material layer 12b is divided into a first control gate CG1 and a second control gate CG2, the dielectric layer 10b is divided into a first dielectric layer D1 and a second dielectric layer D2, and the dielectric layer 10c is divided into a third dielectric layer D3 and a fourth dielectric layer D4. The structures of the first floating gate FG1 and the second floating gate FG2 are mirror-symmetrical, and the structures of the first control gate CG1 and the second control gate CG2 are mirror-symmetrical.

In addition, the formation of the first trench T1 may include using two types of etching gases. During the etching process, one gas is used to etch the dielectric layer 10c, the conductive material layer 12b, the dielectric layer 10b, and the conductive material layer 12a, while the other gas is used to simultaneously form a protective layer (not shown) on the dielectric layer 10c, the conductive material layer 12b, the dielectric layer 10b, and the conductive material layer 12a. In this way, the first trench T1 is formed, with the bottom of the first trench T1 having two pointed corners P.

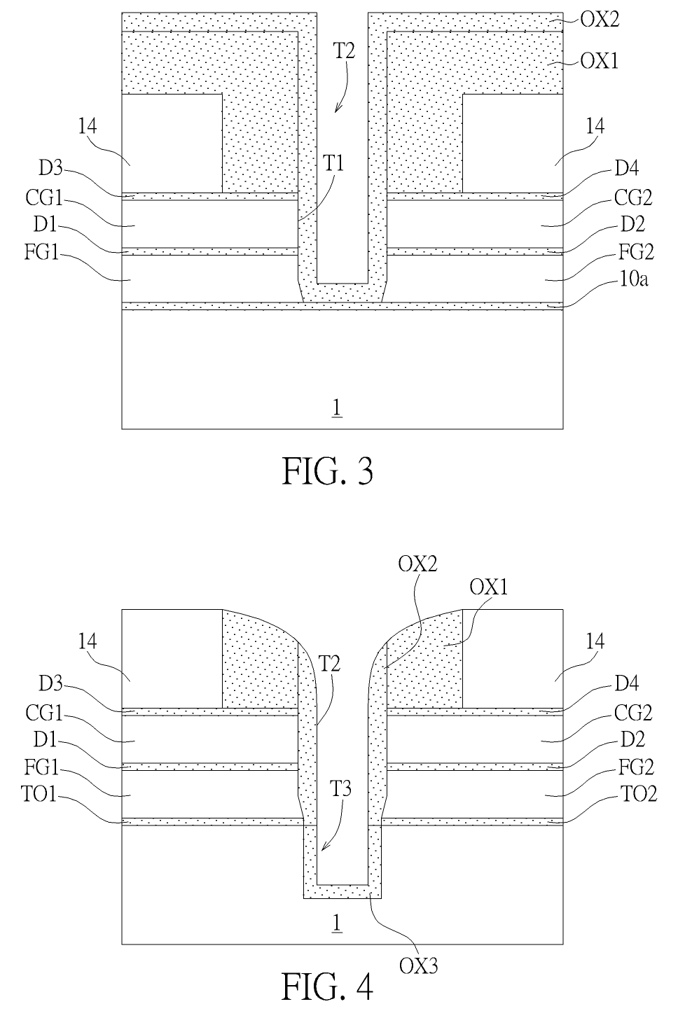

As shown in FIG. 3, a second silicon oxide layer OX2 is conformally formed to cover the first trench T1. Therefore, a second trench T2 is defined in the second silicon oxide layer OX2. As shown in FIG. 4, after etching the second silicon oxide layer OX2 at a bottom of the second trench T2, the etching continues into the dielectric layer 10a and the semiconductor substrate 1 to form a third trench T3 extending into the semiconductor substrate 1. A heated oxidation process is then performed to form a third silicon oxide layer OX3 on an outer sidewall of the third trench T3. At this point, the dielectric layer 10a is divided into a first tunnel dielectric layer TO1 and a second tunnel dielectric layer TO2.

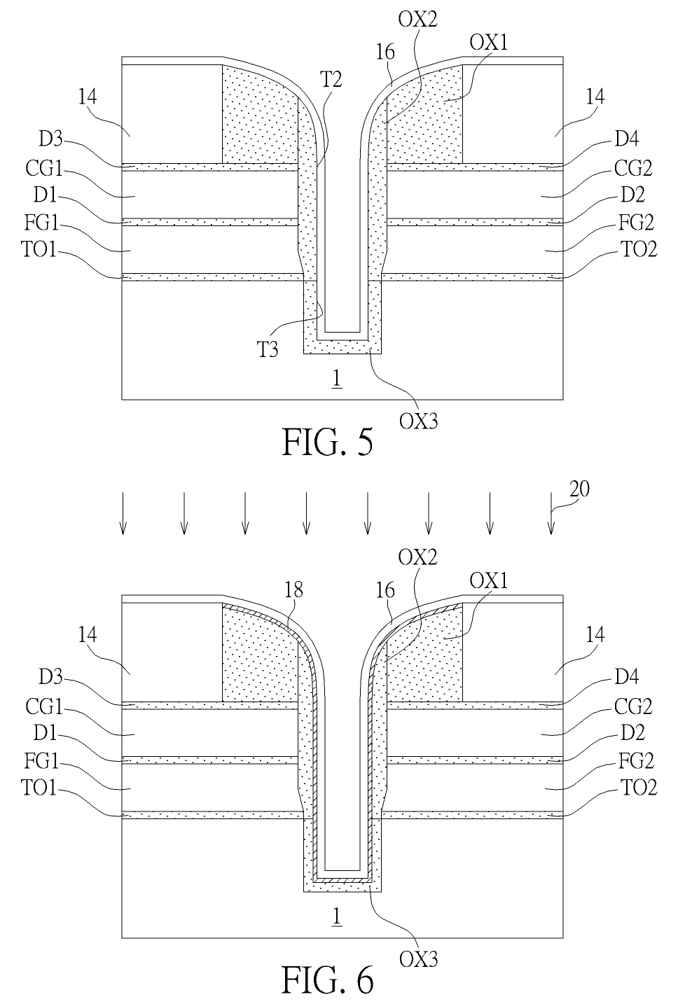

As shown in FIG. 5, a titanium nitride layer 16 is formed to cover the second trench T2 and the third trench T3, with the titanium nitride layer 16 directly contacting the second silicon oxide layer OX2 and the third silicon oxide layer OX3. The titanium nitride layer 16 can be formed by a physical vapor deposition (PVD), a chemical vapor deposition (CVD), a sputtering process, or other suitable methods.

As shown in FIG. 6, a nitridation process 20 is performed. The nitridation process 20 includes using a nitrogen-containing gas as the reaction gas to implant nitrogen atoms into the titanium nitride layer 16, thereby increasing the nitrogen content in the titanium nitride layer 16 to achieve a nitrogen/titanium ratio greater than 1. The nitridation process 20 is preferably a plasma process, which involves using a nitrogen gas and hydrogen gas mixture as the reaction gas. The flow rate of nitrogen gas is between 1000 to 1400 standard cubic centimeters per minute (sccm), and the flow rate of hydrogen gas is between 1600 to 2000 sccm. According to a preferred embodiment of the present invention, the flow rate of nitrogen gas is 1200 sccm, and the flow rate of hydrogen gas is 1800 sccm. The plasma process is operated for a time greater than 15 seconds, with a temperature greater than 300° C. , and a pressure greater than 1.2 millitorr (mtorr).

During the nitridation process 20, nitrogen atoms are also implanted into the first silicon oxide layer OX1, the second silicon oxide layer OX2, and the third silicon oxide layer OX3, causing portions of the first silicon oxide layer OX1, the second silicon oxide layer OX2, and the third silicon oxide layer OX3 to be converted into a silicon oxynitride layer 18, which directly contacts the titanium nitride layer 16.

As shown in FIG. 7, a metal layer 22 is formed to fill the second trench T2 and the third trench T3. Then, the metal layer 22 is etched back such that a height of a top surface of the metal layer 22 does not exceed heights of the top surfaces of the third dielectric layer D3 and the fourth dielectric layer D4. While etching back the metal layer 22, the first silicon oxide layer OX1, the second silicon oxide layer OX2, the silicon nitride mask layer 14, the titanium nitride layer 16, and the silicon oxynitride layer 18 are also etched simultaneously. As a result, the remaining top surface of the metal layer 22, the two ends of the titanium nitride layer 16, and the two ends of the silicon oxynitride layer 18 together form a profile recessed into the substrate 1.

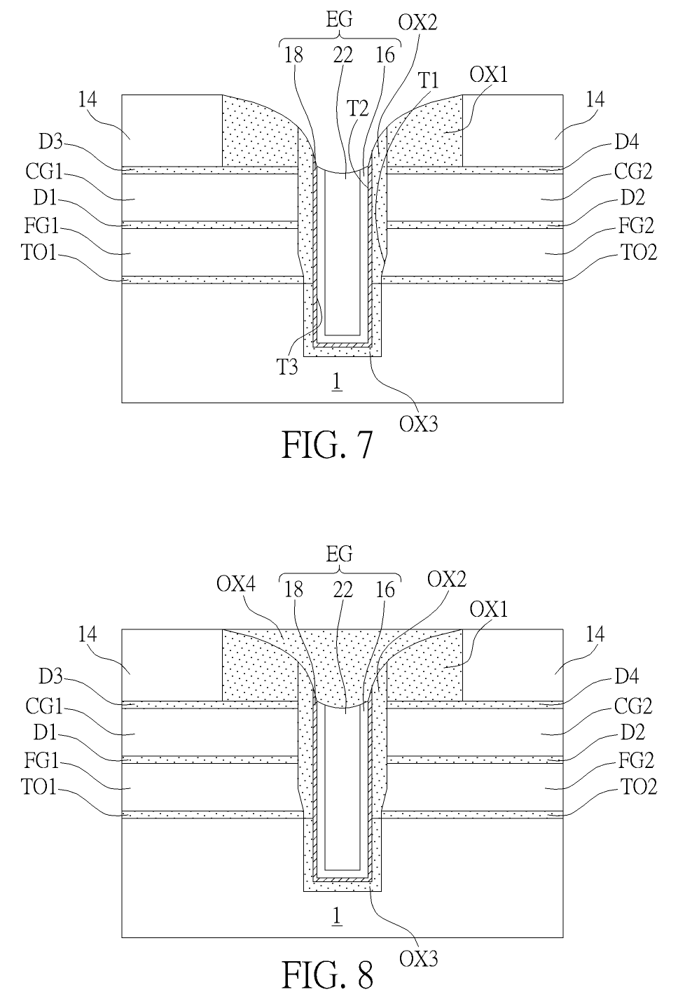

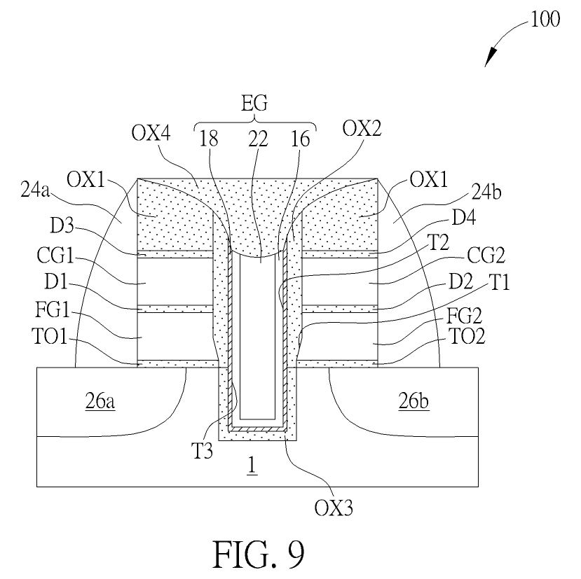

As shown in FIG. 8, a fourth silicon oxide layer OX4 is formed to cover the metal layer 22, such that a top surface of the fourth silicon oxide layer OX4 is aligned with the top surface of the silicon nitride mask layer 14. As shown in FIG. 9, after the silicon nitride mask layer 14 is removed completely, part of the first control gate CG1, part of the second control gate CG2, part of the first floating gate FG1, part of the second floating gate FG2, part of the first dielectric layer D1, part of the second dielectric layer D2, part of the third dielectric layer D3, part of the fourth dielectric layer D4, part of the first tunnel dielectric layer TO1, and part of the second tunnel dielectric layer TO2 are removed by using the fourth silicon oxide layer OX4 and the first silicon oxide layer OX1 as a mask.

Subsequently, spacers 24a and 24b are formed. The spacer 24a is located on the sidewalls of the first tunnel dielectric layer TO1, the first floating gate FG1, the first dielectric layer D1, the first control gate CG1, the third dielectric layer D3, and the first silicon oxide layer OX1. The spacer 24b is located on the sidewalls of the second tunnel dielectric layer TO2, the second floating gate FG2, the second dielectric layer D2, the second control gate CG2, the fourth dielectric layer D4, and the first silicon oxide layer OX1. Then, two source/drain doped regions 26a and 26b are formed in the substrate 1. The source/drain doped region 26a is located below the spacer 24a, and the source/drain doped region 26b is located below the spacer 24b. At this point, a flash memory 100 according to the present invention is completed.

As shown in FIG. 9, a flash memory 100 of the present invention includes a substrate 1. A first floating gate FG1 and a second floating gate FG2 are disposed on the substrate 1. A first control gate CG1 is disposed on the first floating gate FG1, and a second control gate CG2 is disposed on the second floating gate FG2. A first tunnel dielectric layer TO1 is disposed between the first floating gate FG1 and the substrate 1, and a second tunnel dielectric layer TO2 is disposed between the second floating gate FG2 and the substrate 1. A first dielectric layer D1 is disposed between the first floating gate FG1 and the first control gate CG1, and a second dielectric layer D2 is disposed between the second floating gate FG2 and the second control gate CG2. An erase gate EG is disposed on one side of the first control gate CG1, and the erase gate EG is located between the first floating gate FG1 and the second floating gate FG2, as well as between the first control gate CG1 and the second control gate CG2. The erase gate EG includes a metal layer 22, a titanium nitride layer 16, and a silicon oxynitride layer 18. The silicon oxynitride layer 18 surrounds the titanium nitride layer 16, and the titanium nitride layer 16 surrounds the metal layer 22. Specifically, the silicon oxynitride layer 18 contacts the titanium nitride layer 16, and the titanium nitride layer 16 contacts the metal layer 22. The second silicon oxide layer OX2 and the third silicon oxide layer OX3 contact the silicon oxynitride layer 18. The second silicon oxide layer OX2 and the third silicon oxide layer OX3 surround the erase gate EG. In addition, source/drain doped regions 26a and 26b are respectively embedded in the substrate 1 at one side of the first floating gate FG1 and one side of the second floating gate FG2.

The metal layer 22 includes tungsten, nickel, tantalum, titanium, or cobalt. The first control gate CG1, the second control gate CG2, the first floating gate FG1, and the second floating gate FG2 include polysilicon. The first tunnel dielectric layer TO1 and the second tunnel dielectric layer TO2 include silicon oxide. The first dielectric layer D1 and the second dielectric layer D2 include silicon oxide, an oxide/nitride/oxide (ONO) stack, or a multilayer stack of alternating layers of silicon oxide and silicon nitride. The first silicon oxide layer OX1, the second silicon oxide layer OX2, the third silicon oxide layer OX3, and the fourth silicon oxide layer OX4 each include silicon dioxide or a silicon-rich oxide (SRO) layer. The spacers 24a and 24b include silicon nitride.

According to a preferred embodiment of the present invention, the thickness of the titanium nitride layer 16 is 4 to 6 times the thickness of the silicon oxynitride layer 18. For example, the thickness of the silicon oxynitride layer 18 is preferably between 2 and 5 angstroms, and the thickness of the titanium nitride layer 16 is preferably between 20 and 50 angstroms. In addition, the silicon oxynitride layer 18 continuously covers the titanium nitride layer 16, and the silicon oxynitride layer 18 is a complete and continuous structure; thus, the silicon oxynitride layer 18 fully covers a sidewall and a bottom of the titanium nitride layer 16.

The silicon oxynitride layer 18 of the present invention is an ion-implanted SiON, meaning that it is formed by implanting nitrogen atoms into a silicon oxide layer.

It is noteworthy that the nitrogen-to-titanium ratio in the titanium nitride layer 16 is greater than 1. This is because the titanium nitride layer 16 of the present invention undergoes a nitridation process 20 to intentionally increase its nitrogen content. As the nitrogen content of the titanium nitride layer 16 increases, its work function decreases. The reduction in work function enhances the erase speed of the flash memory 100. Compared with a flash memory device without undergoing the nitridation process, the erase speed of the flash memory 100 of the present invention is improved by more than five times.

In addition, the present invention utilizes an ion implantation to implant nitrogen atoms to increase the nitrogen content in the titanium nitride layer, which offers several significant advantages over titanium nitride formed by chemical vapor deposition (CVD) or physical vapor deposition (PVD) processes to include the nitrogen content. First, ion implantation allows for precise control over both the doping concentration and depth of nitrogen atoms, resulting in a more uniform nitrogen distribution. In contrast, the nitrogen content in deposited films is often influenced by deposition conditions, making it difficult to achieve precise and ideal control.

Furthermore, ion implantation processes are typically carried out at lower temperatures, which is particularly beneficial for thermally sensitive materials. Deposition processes, on the other hand, generally require higher temperatures, which may cause thermal damage to the substrate. Compared to deposition methods, using ion implantation to enhance nitrogen content provides substantial advantages in terms of material quality and performance, especially in processes that require high precision.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory, comprising:
a substrate;
a first floating gate disposed on the substrate;
a first control gate disposed on the first floating gate; and
an erase gate disposed on one side of the first control gate, wherein the erase gate comprises a metal layer, a titanium nitride layer, and a silicon oxynitride layer, the silicon oxynitride layer surrounds the titanium nitride layer, and the titanium nitride layer surrounds the metal layer.

2. The flash memory of claim 1, wherein a nitrogen-to-titanium ratio in the titanium nitride layer is greater than 1.

3. The flash memory of claim 1, wherein a thickness of the titanium nitride
layer is 4 to 6 times a thickness of the silicon oxynitride layer.

4. The flash memory of claim 1, further comprising:
a second floating gate disposed on the substrate;
a second control gate disposed on the second floating gate;
a first tunnel dielectric layer disposed between the first floating gate and the substrate;
a second tunnel dielectric layer disposed between the second floating gate and the substrate;
a first dielectric layer disposed between the first floating gate and the first control gate;
a second dielectric layer disposed between the second floating gate and the second control gate;
a silicon oxide layer surrounding the erase gate;
wherein the erase gate is disposed between the second floating gate and the first floating gate; and
two source/drain doped regions respectively embedded in the substrate at one side of the first floating gate and one side of the second floating gate.

5. The flash memory of claim 4, wherein the silicon oxynitride layer is in contact with the titanium nitride layer, the titanium nitride layer is in contact with the metal layer, and the silicon oxide layer is in contact with the silicon oxynitride layer.

6. The flash memory of claim 4, wherein the metal layer comprises tungsten, nickel, tantalum, titanium, or cobalt.

7. The flash memory of claim 1, wherein a portion of the erase gate is embedded in the substrate.

8. The flash memory of claim 1, wherein the silicon oxynitride layer completely covers a sidewall of the titanium nitride layer and a bottom of the titanium nitride layer.

9. A fabricating method of a flash memory, comprising:
providing a substrate;
forming a first floating gate, a first control gate, a second floating gate, and a second control gate on the substrate, wherein the first control gate is disposed on the first floating gate, the second control gate is disposed on the second floating gate, and a first trench is formed between the first control gate and the second control gate and between the first floating gate and the second floating gate;
forming a second silicon oxide layer to fill the first trench, wherein the second silicon oxide layer defines a second trench;
etching a bottom of the second trench to form a third trench extending from the bottom of the second trench, wherein the third trench is embedded in the substrate;
forming a titanium nitride layer covering the second trench and the third trench;
after forming the titanium nitride layer, performing a nitridation process, wherein the nitridation process comprises implanting nitrogen atoms into the titanium nitride layer using a nitrogen-containing gas as a reactive gas; and
after the nitridation process, forming a metal layer to fill the second trench and the third trench.

10. The fabricating method of a flash memory of claim 9, wherein during the nitridation process, nitrogen atoms are also implanted into the second silicon oxide layer such that a portion of the second silicon oxide layer is converted into a silicon oxynitride layer.

11. The fabricating method of a flash memory of claim 10, wherein a thickness of the titanium nitride layer is 4 to 6 times a thickness of the silicon oxynitride layer.

12. The fabricating method of a flash memory of claim 9, wherein after the nitridation process, a nitrogen-to-titanium ratio in the titanium nitride layer is greater than 1.

13. The fabricating method of a flash memory of claim 9, wherein a flow rate of the nitrogen-containing gas used in the nitridation process ranges from 1000 to 1400 standard cubic centimeters per minute (sccm).

14. The fabricating method of a flash memory of claim 9, wherein the nitrogen-containing gas is nitrogen gas.

15. The fabricating method of a flash memory of claim 9, further comprising, after forming the third trench and before forming the titanium nitride layer, forming a third silicon oxide layer surrounding a bottom of the third trench.

16. The fabricating method of a flash memory of claim 15, further comprising, during the nitridation process, implanting nitrogen atoms into the third silicon oxide layer such that a portion of the third silicon oxide layer is converted into a silicon oxynitride layer.
